(19) United States
(12) Patent Application Publication
(10) Pub. No.: US 2003/0104312 A1
(43) Pub. Date: Jun. 5, 2003

(54) Positive resist composition

(76) Inventors: Yoshiko Miya, Kyoto-shi (JP); Yasunori Uetani, Osaka (JP); Satoshi Yamaguchi, Osaka (JP); Isao Yoshida, Osaka (JP)

Correspondence Address: BIRCH STEWART KOLASCH & BIRCH, PO BOX 747, FALLS CHURCH, VA, 22040-0747, US

(21) Appl. No.: 10/254,841

(22) Filed: Sep. 26, 2002

(30) Foreign Application Priority Data
Sep. 28, 2001 (JP) 2001-300860
Dec. 26, 2001 (JP) 2001-393677

(51) Int. Cl. G03F 7/30; G03C 1/73

(52) U.S. Cl. 430/270.1; 430/281.1; 430/286.1; 430/907; 430/905

(57) ABSTRACT

A chemical amplification type positive resist composition showing a high transmittance at a wavelength of 157 nm and manifesting excellent balance of abilities is provided which comprises a resin having polymerization units of the general formulae (I) and (II) and insoluble or poorly soluble itself in an alkali aqueous solution but becoming soluble in an alkali aqueous solution by the action of an acid; and an acid generating agent:

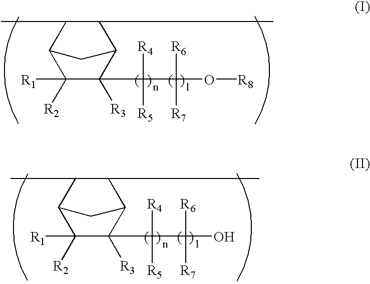

wherein,

R¹, R² and R³ represent each independently hydrogen, halogen, hydroxyl group, alkyl group having 1 to 14 carbon atoms, alicyclic ring or lactone ring,

n and l represent each independently an integer of 0 to 4;

R⁴ and R⁵ represent each independently hydrogen or alkyl group having 1 to 4 carbon atoms;

R⁶ and R⁷ represent an alkyl group having 1 to 6 carbon atoms provided that at least one of R⁶ and R⁷ are substituted by at least one fluorine atom; and

R⁸ represents an acid-unstable group dissociating in the presence of an acid.

### BACKGROUND OF THE INVENTION

### Field of the Invention

The present invention relates to a chemical amplification type positive resist composition.

For fine processing of semiconductors, a lithography process using a resist composition is usually adopted, and in lithography, it is theoretically possible to increase resolution higher when exposure wavelength is shorter as represented by the Rayleigh diffraction limitation formula. As the exposure light source for lithography used for production of semiconductors, there are g ray having a wavelength of 436 nm, i ray having a wavelength of 365 nm, KrF excimer laser having a wavelength of 248 nm and ArF excimer laser having a wavelength of 193 nm, developed in this order, the wavelength becoming shorter year by year. Further, as the exposure light source of the next generation, F₂ excimer laser having a wavelength of 157 nm is promising. For exposure to KrF excimer laser and ArF excimer laser, what is called chemical amplification type resists utilizing the catalytic action of an acid generated by exposure are often used due to excellent sensitivity. Further, also for exposure to F₂ excimer laser, there is a high possibility of use of chemical amplification type resists due to excellent sensitivity. However, conventional resins used in resists for exposure to KrF excimer laser and ArF excimer laser do not manifest sufficient transmittance for lights having wavelengths of 170 nm or less, for example, F₂ excimer laser having a wavelength of 157 nm. When transmittance is low, reverse influences are exerted on various properties such as profile, contrast, sensitivity and the like.

An object of the present invention is to provide a resist composition manifesting excellent transmittance for lights having wavelengths of 170 nm or less and particularly suitable for F₂ excimer laser lithography.

The present inventors have found that transmittance at a wavelength of F₂ excimer laser of 157 nm can be improved and a resist excellent in balance of sensitivity, resolution and the like can be produced by using a resin having a polymerization unit derived from a specific monomer as the resin constituting a resist composition, leading to completion of the present invention.

### SUMMARY OF THE INVENTION

Namely, the present invention provides to a positive resist composition comprising a resin having polymerization units of the general formulae (I) and (II) and insoluble or poorly soluble itself in an alkali aqueous solution but becoming soluble in an alkali aqueous solution by the action of an acid; and an acid generating agent:

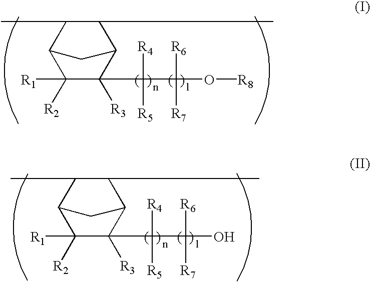

wherein

R¹, R² and R³ represent each independently hydrogen, halogen, hydroxyl group, alkyl group having 1 to 14 carbon atoms, alicyclic ring or lactone ring,

wherein the alkyl group is unsubstituted or has one or more substituents selected from the group consisting of halogens, hydroxyl group and alicyclic rings, and

the alicyclic ring and lactone ring each independently are unsubstituted or have one or more substituents selected from the group consisting of halogens, hydroxyl group and alkyl group;

n and 1 represent each independently an integer of 0 to 4;

R⁴and R⁵ represent each independently hydrogen or alkyl group having 1 to 4 carbon atoms;

R⁶ and R⁷ represent an alkyl group having 1 to 6 carbon atoms provided that at least one of R⁶ and R⁷ are substituted by at least one fluorine atom); and

R⁸ represents an acid-unstable group dissociating in the presence of an acid.

### EMBODIMENTS OF THE INVENTION

The positive resist composition of the present invention comprises a resin having polymerization units of the above-mentioned general formulae (I) and (II), and an acid generating agent.

In the general formulae (I) and (II), R¹, R² and R³ represent each independently hydrogen, halogen, hydroxyl group, alkyl group having 1 to 14 carbon atoms, alicyclic ring or lactone ring. This alkyl group may be unsubstituted or may have at least one substituent selected from the group consisting of halogens, hydroxyl group and alicyclic rings, and is linear, cyclic or branched. The alicyclic ring and lactone ring may be unsubstituted or may each independently have at least one substituent selected from the group consisting of halogens, hydroxyl group and alkyl groups. n and l represent each independently an integer of 0 to 4. R⁴ and R⁵ represent each independently hydrogen or alkyl group having 1 to 4 carbon atoms. R⁶and R⁷ represent an alkyl group having 1 to 6 carbon atoms and either one or both of R⁶ and R⁷ are substituted by at least one fluorine atom. R⁸ represents an acid-unstable group dissociating in the presence of an acid.

Examples of the alkyl group having 1 to 14 carbon atoms optionally substituted by a halogen atom include a methyl group, ethyl group, -propyl group, iso-propyl group, n-butyl group, tert-butyl group, fluoromethyl group, difluoromethyl group, trifluoromethyl group and the like.

As the alicyclic ring, a cyclopentyl group, cyclohexyl group and the like are listed.

As the alkyl group substituted by a hydroxyl group, a hydroxymethyl group and the like are listed.

Either one or both of R⁶ and R⁷ are substituted by at least one fluorine atom. Examples of the alkyl group represented by R⁶ or R⁷ include a methyl group, an ethyl group, a fluoromethyl group, difluoromethyl group, trifluoromethyl group, 2,2,2-trifluoroethyl group, perfluoroethyl group, —C(CF₃)₃ and the like.

As the acid-unstable group dissociating in the presence of an acid represented by R⁸, acid-unstable groups dissociating in the presence of an acid to become soluble in an alkali aqueous solution are listed.

As the acid-unstable group dissociating in the presence of an acid represented by R⁸, groups represented by the general formula (III) are listed:

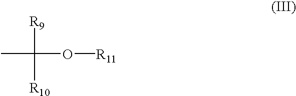

wherein, R⁹ and R¹⁰ represent each independently hydrogen or an alkyl group having 1 to 14 carbon atoms which is unsubstituted or has at least one substituent selected from the group consisting of halogens, hydroxyl group and alicyclic rings; and R¹¹ represents hydrogen, alkyl group having 1 to 14 carbon atoms, alicyclic ring, lactone ring or aromatic ring

wherein the alkyl group is unsubstituted or has one or more substituents selected from the group consisting of halogens, hydroxyl group, alicyclic rings and aromatic rings, and the alicyclic ring, lactone ring and aromatic ring each independently are unsubstituted or have one or more substituents selected from the group consisting of halogens, hydroxyl group and alkyl group.

Specific examples of the acid-unstable group dissociating in the presence of an acid include groups in which quaternary carbon is bonded to an oxygen atom such as a tert-butyl group, tert-butoxycarbonylmethyl group and the like; groups of acetal type such as tetrahydro-2-pyranyl group, tetrahydro-2-furyl group, 1-ethoxyethyl group, 1-(2-methylpropoxy)ethyl group, 1-(2-methoxyethoxy)ethyl group, 1-(2-acetoxyethoxy)ethyl group, 1-[2-(1-adamantyloxy)ethoxy]ethyl group, 1-[2-(1-adamantanecarbonyloxy)ethyl]ethyl group, methoxymethyl group, ethoxymethyl group, pivaloyloxymethyl group, methoxyethoxymethyl group, benzyloxymethyl group and the like.

Particularly, it is preferable to use groups of acetal type such as methoxymethyl group, ethoxymethyl group and the like since they can be easily bought and synthesized.

The acid-unstable group shall be substituted for hydrogen on an alkali-soluble group.

The acid-unstable group can be introduced easily in a resin by performing a known protective group-introduction reaction or conducting copolymerization using, as one monomer, an unsaturated compound having such a group.

In the above-mentioned polymerization unit (I), it is preferable that at least one of R¹ to R⁷ represents a trifluoromethyl group since transmittance under vacuum ultraviolet rays typified by 157 nm is higher. Particularly, it is preferable that the polymerization unit (I) is a group of the following general formula (IV):

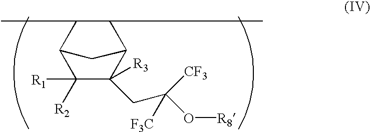

wherein, R¹, R² and R³ are as defined above, and R₈′ represents an acid-unstable group dissociating in the presence of an acid, or hydrogen.

The resin used in the present invention can be obtained by polymerization according to a known polymerization reaction. Namely, polymerization can be conducted by mixing a monomer which can derive the above-mentioned polymerization unit with a catalyst and stirring the mixture at suitable temperature, in the presence or absence of a solvent. The resulted polymer can be purified by precipitation in a suitable solvent.

Mentioned as the resin in the present invention are resins obtained by partial substitution of an acid-unstable group dissociating in the presence of an acid for hydrogen of a hydroxyl group in a resin having a polymerization unit of the general formula (II):

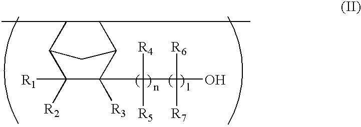

wherein, R₁, R₂, R₃, R₄, R₅, R₆ and R₇ are as defined above. n and 1 are as defined above.

It is generally preferable that the resin used in the present invention contains 15 to 50 mol % of a polymerization unit having a group dissociating by the action of an acid though the content varies depending on the kind of radiation for patterning exposure, the kind of a group dissociating by the action of an acid, and the like.

As the polymerization units of the formulae (I) and (II), for example, those of the following formulae, and the like are listed.

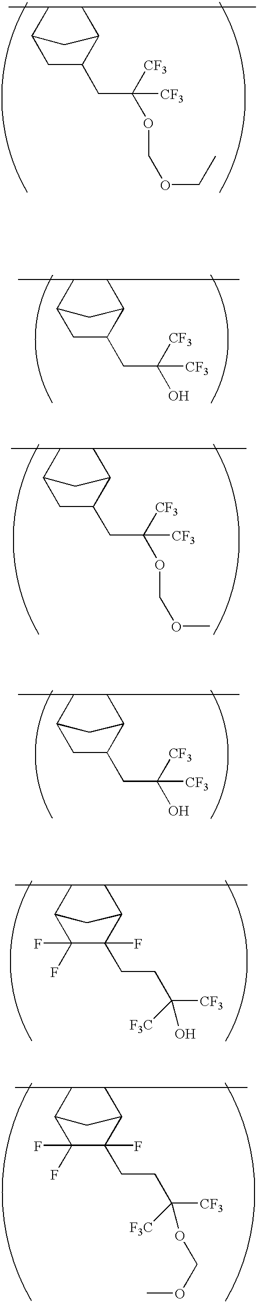

Mentioned as the resin in the present invention are resins having two or more polymerization units of the general formula (I) in which R⁸ represents mutually different moieties.

The acid generating agent used in the present invention is not particularly restricted providing the acid generating agent is decomposed to generate an acid by allowing radiations such as light, electron beam and the like to act on the acid generating agent itself or a resist composition containing the acid generating agent.

An acid generated from the acid generating agent acts on the above-mentioned resin to dissociate a group dissociating by the action of an acid in the resin.

Examples of the acid generating agent include onium salt compounds, organohalogen compounds, sulfone compounds, sulfonate compounds and the like.

As the sulfonate compound, compounds of the general formula (V) are listed:

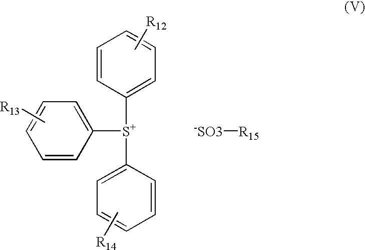

wherein, R¹², R¹³ and R¹⁴ represent hydrogen, halogen, hydroxyl group, alkyl group having 1 to 14 carbon atoms, or alkoxy group. This alkyl group may optionally have at least one substituent selected from the group consisting of halogens, hydroxyl group, alicyclic rings and aromatic rings. The alkoxy group may optionally have at least one substituent selected from the group consisting of halogens, hydroxyl group, alicyclic rings and aromatic rings. The alicyclic ring, lactone ring and aromatic ring may each independently and optionally have at least one substituent selected from the group consisting of halogens, hydroxyl group and alkyl groups. R¹⁵ represents an alkyl chain having 8 or more carbon atoms optionally substituted by halogen, and may be linear, branched or alicyclic.

Of these compounds, preferable are those in which R¹⁵ represents a fluorocarbon chain obtained by substituting all hydrogen atoms in an alkyl chain having 8 or more carbon atoms by fluorine.

Specific examples of such acid generating agents include the following compounds.

Diphenyliodonium trifluoromethanesulfonate,

4-methoxyphenylphenyliodinium hexafluoroantimonate,

4-methoxyphenylphenyliodinium trifluoromethanesulfonate,

bis(4-tert-butylphenyl)iodonium tetrafluoroborate

bis(4-tert-butylphenyl)iodonium hexafluorophosphate,

bis(4-tert-butylphenyl)iodonium hexafluoroantimonate

bis(4-tert-butylphenyl)iodonium trifluoromethanesulfonate,

triphenylsulfonium hexafluorophosphate,

triphenylsulfonium hexafluoroantimonate,

triphenylsulfonium trifluoromethanesulfonate,

4-methoxyphenyldiphenylsulfonium hexafluoroantimonate,

4-methoxyphenyldiphenylsulfonium trifluoromethanesulfonate,

p-tolyldiphenylsulfonium trifluoromethanesulfonate,

p-tolyldiphenylsulfonium perfluorobutanesulfonate,

p-tolyldiphenylsulfonium perfluorooctanesulfonate,

2,4,6-trimethylphenyldiphenylsulfonium trifluoromethanesulfonate,

4-tert-butylphenyldiphenylsulfonium trifluoromethanesulfonate,

4-phenylthiophenyldiphenylsulfonium hexafluorophosphate,

4-phenylthiophenyldiphenylsulfonium hexafluoroantimonate,

1-(2-naphtholylmethyl)thiolanium hexafluoroantimonate,

1-(2-naphtholylmethyl)thiolanium trifluoromethanesulfonate,

4-hydroxy-1-naphthyldimethylsulfonium hexafluoroantimonate,

4-hydroxy-1-naphthyldimethylsulfonium trifluoromethanesulfonate,

cyclohexylmethyl(2-oxocyclohexyl)sulfonium trifluoromethanesulfonate,

cyclohexylmethyl(2-oxocyclohexyl)sulfonium perfluorobutanesulfonate,

cyclohexylmethyl(2-oxycyclohexyl)sulfonium perfluorootcanesulfonate,

2-methyl-4,6-bis(trichloromethyl)-1,3,5-triazine,

2,4,6-tris(trichloromethyl)-1,3,5-triazine

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolan-5-yl)-4,6-bis(trichloromey thyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(3,4-dimethoxystyryl)-4,6-bis(trichloromethyl)-1,3,5-triazine,

2-(2,4-dimethoxystyryl)-4,6-bis(trichloromethyl)-1,3,5-triazine,

2-(2-methoxystyryl)-4,6-bis(trichloromethyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine,

1-benzoyl-1-phenylmethyl p-toluenesulfonate (generally called benzoin tosylate),

2-benzoyl-2-hydroxy-2-phenylethyl p-toluenesulfonate (generally called α-methylolbenzoin tosylate),

1,2,3-benzenetolyl trismethanesulfonate,

2,6-dinitrobenzyl p-toluenesulfonate,

2-nitrobenzyl p-toluenesulfonate,

4-nitrobenzyl p-toluenesulfonate,

diphenyl disulfone,

di-p-tolyl disulfone

bis(phenylsulfonyl)diazomethane,

bis(4-chlorophenylsulfonyl)diazomethane,

bis(p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane,

N-(phenylsulfonyloxy)succinimide,

N-(trifluoromethylsulfonyloxy)succinimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide and the like.

The positive resist composition of the present invention can improve deterioration in abilities due to deactivation of an acid following leaving after exposure, by adding as a quencher a basic compound, such as amines. Specific examples of the basic compound used as a quencher include compounds of the following formulae.

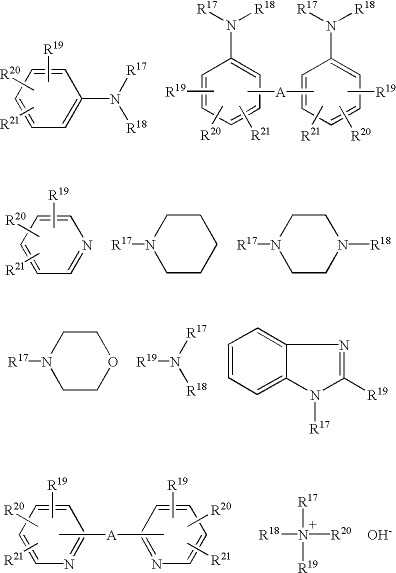

In the above formulae, R¹⁷, R¹⁸, R¹⁹, R²⁰ and R²¹ represent each independently hydrogen, alkyl, cycloalkyl or aryl. The alkyl, cycloalkyloraryl maybe each independently substituted with, a hydroxyl group, amino group or alkoxy group having 1 to 6 carbon atoms. This amino group may be substituted with an alkyl group having 1 to 18 carbon atoms. This alkyl preferably has about 1 to 8 carbon atoms, this cycloalkyl preferably has about 5 to 10 carbon atoms, and this aryl preferably has about 6 to 10 carbon atoms.

A represents alkylene, carbonyl, imino, sulfide or disulfide. The alkylene preferably has about 2 to 6 carbon atoms.

may have any of a linear structure and a branched structure providing they can take both structures.

In view of resolution, it is preferable to use a compound of the following formula as a quencher:

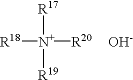

wherein R¹⁷ to R²⁰ have the same meaning as above.

Specific examples of such compounds include tetramethylammonium hydroxide, tetrabutylammonium hydroxide, tetrahexylammonium hydroxide, tetraoctylammonium hydroxide, phenyltrimethylammonium hydroxide, 3-trifluoromethyl-phenylammonium hydroxide and the like.

It is preferable that the chemical amplification type positive resist composition of the present invention contains the resin in an amount of 80 to 99.9% by weight, and an acid generating agent in an amount of 0.1 to 20% by weight based on total solid content in the composition.

When a basic compound is used as a quencher, it is preferable that the composition of the present invention contains the basic compound in an amount of 0.001 to 1% by weight based on total solid content in the composition.

The composition of the present invention can also contain a small amount of various additives such as sensitizers, solution suppressing agents, other resins, surfactants, stabilizers, dyes and the like, if necessary.

The resist composition of the present invention is usually used as a liquid containing the above-mentioned components dissolved in a solvent, and the liquid is applied on a substrate such as a silicon wafer and the like according to an ordinary method such as spin coating and the like.

Any solvents may be used here providing they dissolve each component, show suitable drying speed, and give a uniform and smooth film after evaporation of a solvent. Solvents generally used in this field can be used as the solvent.

Examples thereof include glycol ether esters such as ethylcellosolve acetate, methylcellosolve acetate or propylene glycolmonomethyl ether acetate; esters such as ethyl lactate, butyl acetate, amyl acetate or ethyl pyruvate; ketones such as acetone, methyl isobutyl ketone, 2-heptanone or cylohexanone; and cyclic esters such as γ-butyrolactone; and the like. These solvents can be used each alone or in combination of two or more.

On a resist film applied on a substrate and dried, exposure treatment for patterning is performed, then, heating treatment for promoting a protective group-removing reaction is conducted. Thereafter, the resist film is developed with an alkali developer. The alkali developer used here can be selected from various alkaline aqueous solutions used in this field, and generally, often used are aqueous solutions of tetramethylammonium hydroxide and (2-hydroxyethyl)trimethylammonium hydroxide.

The following examples will illustrate the present invention further specifically, but do not limit the scope of the present invention at all. In examples, parts representing content or use amount are by weight unless otherwise stated. The weight-average molecular weight (Mw) and polydispersion (Mw/Mn) were measured by gel permeation chromatography using polystyrene as a standard.

### Resin Synthesis Example 1

### Synthesis of Poly 5-norbornene-2-(2,2-ditrifluoromethyl-2-hydroxy)ethyl (hereinafter, sometimes referred to as pNBHFA)

4.3 g of silver tetrafluoroborate was weighed in a screw tube, to this was added 45 g of 1,2-dichloroethane, then, 2.0 g of π-allylparadiumchloro bridge dimer, and the mixture was stirred to prepare a complex. After stirring for 30 minutes, the complex was filtrated through a filter, and dropped into a mixed solution composed of 75 g of 5-norbornene-2-(2,2-ditrifluoromethyl-2-hydroxy)ethyl (available from Central Glass Co., Ltd.) and 75 g 1,2-dichloroethane in a flask. After stirring at room temperature for 24 hours, a suitable amount of tetrachlorofuran was added, hydrogen was blown into the solution, and the precipitated black material was removed by filtration. In the resulted filtrate, the solvent was substituted by an ethyl acetate solution, and the filtrate was washed with water six times. The organic layer was concentrated, then, diluted with a suitable amount of acetone, and charged in heptane to cause precipitation of a resin. Thereafter, the solvent was discarded by decantation, and the solid was dried under vacuum. 60.7 g of a crystal of 5-norbornene-2-(2,2-ditrifluoromethyl -2-hydroxy)ethyl (pNBHFA) was obtained. The weight-average molecular weight was about 14300 and the degree of dispersion was 1.87 (GPC method; reduced by polystyrene).

### Resin Synthesis Example 2

### Synthesis Example of Resin A1

Into a flask were charged 6 g of pNBHFA obtained in Synthesis Example 1, 60 g of methyl isobutyl ketone and 7.5 g of diisopropylethylamine, and 3.9 g of methoxymethyl chloride was dropped, and they were reacted at room temperature. 14 hours after initiation of the reaction, a suitable amount of methyl isobutyl ketone was added and the mixture was washed with water six times. The organic layer was concentrated, then, diluted with a suitable amount of acetone, and charged into a mixed solution composed of 360 g of water and 240 g of methanol, to precipitate a resin. After filtration, the solid was dried under reduced pressure. The weight of a crystal of a resin A1 obtained by partial methoxymethylation of pNBHFA was 6.0 g. The methoxymethylated ratio was analyzed by a nuclear magnetic resonance (¹H-NMR) analyzer to be about 24%.

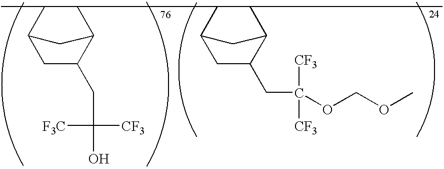

### Resin Synthesis Example 3

### Synthesis Example of Resin A2

Into a flask were charged 2.5 g of pNBHFA obtained in Synthesis Example 1, 25 g of methyl isobutyl ketone and 1.8 g of diisopropylethylamine, and 1.1 g of ethoxymethyl chloride was dropped, and they were reacted at room temperature. 14 hours after initiation of the reaction, a suitable amount of methyl isobutyl ketone was added and the mixture was washed with water six times. The organic layer was concentrated, then, diluted with a suitable amount of acetone, and charged into a mixed solution composed of 150 g of water and 100 g of methanol, to precipitate a resin. After filtration, the solid was dried under reduced pressure. The weight of a crystal of a resin A2 obtained by partial ethoxymethylation of pNBHFA was 2.3 g. The ethoxymethylated ratio was analyzed by a nuclear magnetic resonance (¹H-NMR) analyzer to be about 20%.

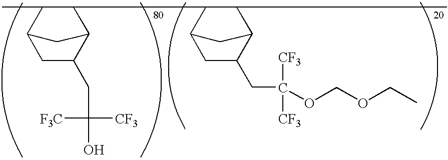

### Resin Synthesis Example 4

### Synthesis Example of Resin A3

Into a flask were charged 6 g of pNBHFA obtained in Synthesis Example 1, 60 g of methyl isobutyl ketone and 5.8 g of diisopropylethylamine, and 3.5 g of ethoxymethyl chloride was dropped, and they were reacted at room temperature. 14 hours after initiation of the reaction, a suitable amount of methyl isobutyl ketone was added and the mixture was washed with water six times. The organic layer was concentrated, then, diluted with a suitable amount of acetone, and charged into a mixed solution composed of 360 g of water and 240 g of methanol, to precipitate a resin. After filtration, the solid was dried under reduced pressure. The weight of a crystal of a resin A3 obtained by partial ethoxymethylation of pNBHFA was 5.3 g. The ethoxymethylated ratio was analyzed by a nuclear magnetic resonance (¹H-NMR) analyzer to be about 25%.

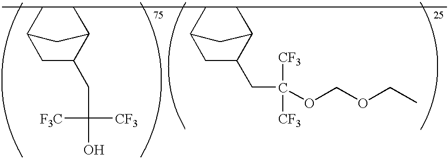

### Resin Synthesis Example 5

### Synthesis Example of Resin A4

Into a flask were charged 8.0 g of pNBHFA obtained in Synthesis Example 1, 40 g of tetrahydrofuran and 0.4 g of dimethylaminopyridine, and di-tert-butyl dicarbonate was added, and they were reacted at room temperature for 6 hours. Thereafter, a suitable amount of methyl isobutyl ketone was added and the mixture was washed twice with 5% acetic acid water, then, washed six times with ion exchanged water. The organic layer was concentrated, then, diluted with a suitable amount of acetone, and charged into a mixed solution composed of 240 g of water and 360 g of methanol, to precipitate a resin. After decantation, the solid was dried under reduced pressure, and the weight of a crystal of a resin A8 obtained by partial tert-butoxycarbonylation of pNBHFA was 7.7 g. The tert-butoxycarbonylated ratio could be analyzed by a nuclear magnetic resonance (¹³C-NMR) analyzer to be about 11%. Further, into a flask was charged 5.0 g of a resin AY obtained in Synthesis Example 10 described later, 50 g of methyl isobutyl ketone and 4.4 g of diisopropylethylamine, and 2.3 g of methoxymethyl chloride was dropped, and they were reacted at room temperature. 14 hours after initiation of the reaction, a suitable amount of methyl isobutyl ketone was added and the mixture was washed with water six times. The organic layer was concentrated, then, diluted with a suitable amount of acetone, and charged into a mixed solution composed of 300 g of water and 200 g of methanol, to precipitate a resin. After filtration, the solid was dried under reduced pressure. The weight of a crystal of a resin A4 obtained by partial methoxymethylation of pNBHFA was 3.8 g. The methoxymethylated ratio was analyzed by a nuclear magnetic resonance (¹H-NMR) analyzer to be about 17%.

### Resin Synthesis Example 6

### Synthesis Example of resin A5

Into a flask were charged 3.0 g of pNBHFA obtained in Synthesis Example 1, 30 g of methyl isobutyl ketone and 4.2 g of diisopropylethylamine, and 3.4 g of 2-methoxyethoxymethyl chloride was dropped, and they were reacted at room temperature. 15 hours after initiation of the reaction, 1.7 g of diisopropylethylamine, and 1.4 g of 2-methoxyethoxymethyl chloride was added, and the reaction mass was stirred for 7 more hours at room temperature. Thereafter, a suitable amount of methyl isobutyl ketone was added and the mixture was washed with water six times. The organic layer was concentrated, then, diluted with a suitable amount of acetone, and charged into a mixed solution composed of 180 g of water and 120 g of methanol, to precipitate a resin. After filtration, the solid was dried under reduced pressure. The weight of a crystal of a resin A5 obtained by partial 2-methoxyethoxymethylation of pNBHFA was 2.6 g. The 2-methoxyethoxymethylated ratio was analyzed by a nuclear magnetic resonance (¹H-NMR) analyzer to be about 23%.

### Resin Synthesis Example 7

### Synthesis Example of Resin A6

In a four-necked flask, 3.00 of pNBHFA obtained in Synthesis Example 1 was added and dissolved in 30.00 g of methyl isobutyl ketone. 3.39 g of diisopropylethylamine was added, then, into this was dropped 3.34 g of benzyl chloromethyl ether, and the mixture was stirred at room temperature for 21 hour. After reaction, washing with water was repeated. The organic layer was concentrated, and dropped into n-hexane. The resulted agglomerate was decanted, then, dried under reduced pressure. The following resin having an average molecular weight of about 13000 was obtained. According to NMR, the benzyloxymethylated ratio was calculated to be 13%. This copolymer is called resin A6.

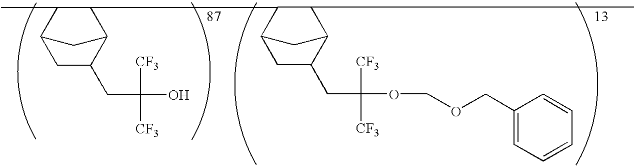

### Resin Synthesis Example 8

### Synthesis Example of Resin A7

In a four-necked flask, 3.00 of pNBHFA obtained in Synthesis Example 1 was added and dissolved in 15.00 g of DMF. 0.17 g of potassium iodide and 0.57 g of potassium carbonate were added, then, 0.41 g of chloromethyl pivalate was added, and the mixture was stirred at room temperature for 4hours. After reaction, methyl isobutyl ketone was added for dilution, then, washing with water was repeated. The organic layer was concentrated, and dropped into n-hexane. The resulted agglomerate was decanted, then, dried under reduced pressure. The following resin having an average molecular weight of about 13000 was obtained. According to NMR, the pivaloyloxymethylated ratio was calculated to be 15%. This copolymer is called resin A7.

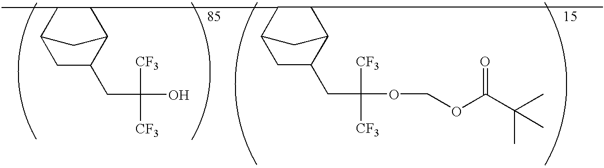

### Resin Synthesis Example 9

### Synthesis Example of Resin AX (synthesis of 2-ethyl-2-adamantyl methacrylate/3-hydroxy-1-adamantyl methacrylate/α-methacryloyloxy-γ-butyrolactone copolymer (resin AX))

2-ethyl-2-adamantylmethacrylate, 3-hydroxy-1-adamantyl methacrylate and α-methacryloyloxy-γ-butyrolactone were charged at a molar ratio of 2:1:1 (20.0 g:8.9 g:6.8 g), and methyl isobutyl ketone of an amount of 2-fold by weight of the total monomer amount was added to give a solution. To this was added azobisisobutyronitrile as an initiator in an amount of 2 mol % based on the total monomer amount, and the mixture was heated up to 85° C. and stirred for about 5 hours. The reaction mass was cooled, then, poured into a large amount of heptane to cause precipitation. This operation repeated three times for purification. As a result, a copolymer having a weight-average molecular weight of about 8000 was obtained in a yield of 60%. This resin is called resin AX.

### Resin Synthesis Example 10

### Synthesis Example of Resin AY

Into a flask were charged 2.5 g of pNBHFA obtained in Synthesis Example 1, 12.5 g of tetrahydrofuran and 0.11 g of dimethylaminopyridine, and 1.0 g of di-tert-butyl dicarbonate was added, and they were reacted at room temperature for 6 hours. Thereafter, a suitable amount of methyl isobutyl ketone was added and the mixture was washed twice with 5% acetic acid water, then, washed six times with ion exchanged water. The organic layer was concentrated, then, diluted with a suitable amount of acetone, and charged into a mixed solution composed of 125 g of water and 75 g of methanol, to precipitate a resin. After decantation, the solid was dried under reduced pressure, and the weight of a crystal of a resin obtained by partial tert-butoxycarbonylation of the NBHFA homopolymer was 2.6 g. The tert-butoxycarbonylated ratio could be analyzed by a nuclear magnetic resonance (¹³C-NMR) analyzer to be about 30%.

### EXAMPLES AND COMPARATIVE EXAMPLES

A resin, a photo acid generating agent and a quencher of the kinds and amounts showing in Table 1 were combined and dissolved in propylene glycol monomethyl ether acetate/γ-butyrolactone=95/5, and then filtrated through a fluorine resin filter having a pore diameter of 0.2 μm, to prepare a resist solution.

Photo Acid Generating Agent

A p-tolyldiphenylsulfonium perfluorooctanesulfoante

B p-tolyldiphenylsulfonium perfluorobutanesulfoante

C p-tolyldiphenylsulfonium perfluoromethanesulfonate

Quencher

D 2,6-diisopropylaniline

E tetrabutylammonium hydrooxide

F tetrahexylammonium hydrooxide

G tetraoctylammonium hydrooxide

H phenyltrimethylammonium hydrooxide

I 3-trifluoromethyl-phenyltrimethylammonium hydroxide

TABLE 1

| | | Photo acid | |
|---|---|---|---|
| Example No. | Resin | generating agent | Quencher |
| Example 1 | A1 (10) | A (0.2) | D (0.0075) |
| Example 2 | A1 (10) | A (0.2) | E (0.03) |
| Example 3 | A2 (10) | A (0.2) | D (0.0075) |
| Example 4 | A3 (10) | A (0.2) | D (0.0075) |
| Example 5 | A4 (10) | A (0.2) | D (0.0075) |
| Example 6 | A5 (10) | A (0.2) | D (0.0075) |
| Example 7 | A6 (10) | A (0.2) | D (0.0075) |
| Example 8 | A7 (10) | A (0.2) | D (0.0075) |
| Example 9 | A1 (10) | B (0.15) | D (0.0075) |
| Example 10 | A1 (10) | C (0.11) | D (0.0075) |
| Example 11 | A1 (10) | A (0.2) | F (0.03) |
| Example 12 | A1 (10) | A (0.2) | G (0.03) |
| Example 13 | A1 (10) | A (0.2) | H (0.03) |
| Example 14 | A1 (10) | A (0.2) | I (0.03) |
| Example 15 | AY (10) | A (0.2) | E (0.03) |
| Comparative | AX (10) | A (0.2) | D (0.0075) |
| example 1 | | | |
| Comparative | AY (10) | A (0.2) | D (0.0075) |
| example 2 | | | |

(1) Sensitivity, Resolution and Profile (by ArF excimer)

“DUV-30J-14” which is a composition for organic reflection preventing film manufactured by Brewer was applied and baked at 215° C. for 60 seconds to form an organic reflection preventing film having a thickness of 1600 Å on a silicon water, and on this, the resist solution prepared above was spin-coated so that the film thickness after drying was 0.19 μm. After application of the resist solution, prebake was conducted at 160° C. for 60 seconds in Examples 1 to 15 and Comparative Example 2 and at 130° C. for 60 seconds in Comparative Example 1, on a direct hot plate. The wafer on which a resist film had thus been formed was exposed to line and space pattern using ArF excimer stepper (“NSR ArF” manufactured by Nikon Corp., NA=0.55, σ=0.6) while changing the exposure amount stepwise.

After exposure, post exposure bake was conducted at 130° C. for 60 seconds on a hot plate, further, paddle development was conducted for 60 seconds with a 2.38 wt % tetramethylammonium hydroxide aqueous solution.

Line and space pattern on the organic reflection preventing film substrate after development was observed by a scanning electron microscope, and the effective sensitivity and resolution were checked by the following methods and the results are shown in Table 2.

Effective sensitivity: It is represented by exposure amount under which line and space pattern of 0.18 μm shows a ratio of 1:1.

Resolution: It is represented by the minimum size of line and space pattern separating at the exposure amount of the effective sensitivity.

Profile T/B: It is represented by a ratio of the length (T) of the upper edge of line section of 0.18 μm to the length of the bottom edge (B). When the profile is nearer to 1, the profile is better.

(2) Exposure Sensitivity at 157 nm

“DUV-30J-14” which is a composition for organic reflection preventing film manufactured by Brewer was applied and baked at 215° C. for 60 seconds to form an organic reflection preventing film having a thickness of 1600 Å on a silicon water, and on this, the resist solution prepared above was spin-coated so that the film thickness after drying was 0.13 μm. Prebake was conducted at 160° C. for 60 seconds in Examples 1 to 6 and Comparative Examples 2 to 4 and at 130° C. for 60 seconds in Comparative Example 1, on a direct hot plate. The wafer on which a resist film had thus been formed was exposed under open frame using a simple type F₂ excimer laser exposing machine (“VUVES-4500” purchased from Lithotech Japan K.K.) while changing the exposure amount stepwise. After exposure, post exposure bake (PEB) was conducted at 130° C. for 60 seconds on a hot plate, further, paddle development was conducted for 60 seconds with a 2.38 wt % tetramethylammonium hydroxide aqueous solution. The wafer was visually observed after development, and the minimum exposure amount at which the resist showed film permeation (film permeation sensitivity=Exposure sensitivity at 157 nm) was measured, obtaining results shown in Table 2.

(3) Transmittance at 157 nm

A solution obtained by dissolving only the resist solution previously prepared and a resin in a propylene glycol monomethyl ether acetate solvent was applied on a magnesium fluoride wafer so that the film thickness after drying was 0.1 μm, and pre-baked at 130° C. for 60 seconds on a direct hot plate, to form a resist film. The transmittance at a wavelength of 157 nm of thus formed resist film was measured using a vacuum ultraviolet spectrometer (VUV-200, manufactured by Nippon Bunko K.K.), obtaining results shown in Table 2.

TABLE 2

| | | | | Transmit- | Exposure |
|---|---|---|---|---|---|
| | Effective | | | tance | sensitivity |
| | sensitivity | Resolution | | at 157 nm | at 157 nm |
| Example No. | (mJ/cm²) | (μm) | T/B | (%) | (mJ/cm²) |
| Example 1 | 13 | 0.15 | 0.63 | 64 | 4 |
| Example 2 | 58 | 0.14 | 1.00 | 64 | 20 |
| Example 3 | 12 | 0.16 | 0.77 | 63 | 3 |
| Example 4 | 18 | 0.15 | 0.86 | 63 | 5 |
| Example 5 | 8 | 0.16 | 1.00 | 62 | 2 |
| Example 6 | 17 | 0.15 | 0.33 | 63 | 1.5 |
| Example 7 | — | — | | 61 | — |
| Example 8 | — | — | | 60 | — |
| Example 9 | 12 | 0.16 | 0.17 | 61 | 3 |
| Example 10 | 15 | >0.25 | no resolu- | 61 | 3 |
| | | | tion | | |
| Example 11 | 36 | 0.15 | 0.85 | 63 | 10 |
| Example 12 | 45 | 0.15 | 0.92 | 65 | 15 |
| Example 13 | 14 | 0.15 | 0.73 | 64 | 4 |
| Example 14 | 14 | 0.15 | 0.92 | 65 | 4 |
| Example 15 | 31 | 0.16 | 1.00 | 59 | 15 |
| Comparative | 19 | 0.15 | 0.93 | 21 | 7 |
| example 1 | | | | | |
| Comparative | 2 | 0.21 | no resolu- | 58 | 0.5 |
| example 2 | | | tion | | |

As apparent from Table 2, the resists of the examples show a high transmittance at a wavelength of 157 nm and manifest excellent balance of abilities. Further, as apparent from Table 3, the resists of the examples show further improvement in resolution and profile by using a compound having a structure of the formula (VI) shown in claim 10 as a quencher.

The chemical amplification type positive resist composition of the present invention shows a high transmittance at a wavelength of 157 nm and manifests excellent balance of abilities. Therefore, this composition can manifest excellent abilities as a resist for F₂ laser.

What is claimed is:

1. A positive resist composition comprising a resin having polymerization units of the general formulae (I) and (II) and insoluble or poorly soluble itself in an alkali aqueous solution but becoming soluble in an alkali aqueous solution by the action of an acid; and an acid generating agent: 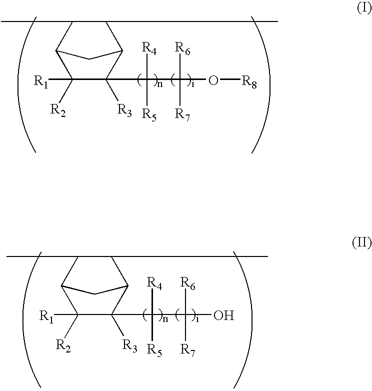
wherein
R¹, R² and R³ represent each independently hydrogen, halogen, hydroxyl group, alkyl group having 1 to 14 carbon atoms, alicyclic ring or lactone ring,
wherein the alkyl group is unsubstituted or has one or more substituents selected from the group consisting of halogens, hydroxyl group and alicyclic rings, and
the alicyclic ring and lactone ring each independently are unsubstituted or have one oe more substituents selected from the group consisting of halogens, hydroxyl group and alkyl group;
n and l represent each independently an integer of 0 to 4;
R⁴ and R⁵ represent each independently hydrogen or alkyl group having 1 to 4 carbon atoms;
R⁶ and R⁷ represent an alkyl group having 1 to 6 carbon atoms provided that at least one of R⁶ and R⁷ are substituted by at least one fluorine atom; and
R⁸ represents an acid-unstable group dissociating in the presence of an acid.

2. The positive resist composition according to claim 1, wherein R⁸ in the formula (I) represents a group of the following formula (III): 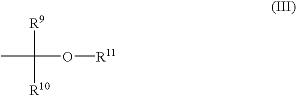
wherein, R⁹ and R¹⁰ represent each independently hydrogen or an alkyl group having 1 to 14 carbon atoms which is unsubstituted or has at least one substituent selected from the group consisting of halogens, hydroxyl group and alicyclic rings; and R¹¹ represents hydrogen, alkyl group having 1 to 14 carbon atoms, alicyclic ring, lactone ring or aromatic ring
wherein the alkyl group is unsubstituted or has one or more substituents selected from the group consisting of halogens, hydroxyl group, alicyclic rings and aromatic rings, and
the alicyclic ring, lactone ring and aromatic ring each independently are unsubstituted or have one or more substituents selected from the group consisting of halogens, hydroxyl group and alkyl group.

3. The positive resist composition according to claim 1, wherein the polymerization unit (I) is a group of the following general formula (IV): 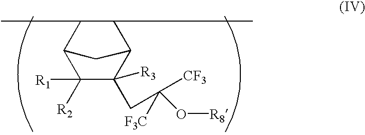
wherein, R¹, R² and R³ areas defined in claim 1, and R₈′ represents an acid-unstable group dissociating in the presence of an acid, or hydrogen.

4. The positive resist composition according to claim 1, which comprises a compound of the following general formula (V) as the acid generating agent: 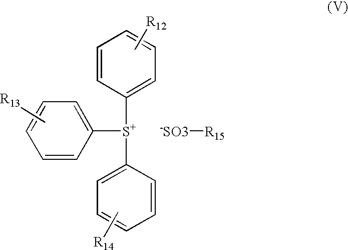
wherein, R¹², R¹³ and R¹⁴ represent hydrogen, halogen, hydroxyl group, alkyl group having 1 to 14 carbon atoms, or alkoxy group,
wherein the alkyl group is unsubstituted or has one or more substituents selected from the group consisting of halogens, hydroxyl group, alicyclic rings and aromatic rings,
the alkoxy group is unsubstituted or has one or more substituents selected from the group consisting of halogens, hydroxyl group, alicyclic rings and aromatic rings, and
the alicyclic ring, lactone ring and aromatic ring each independently are unsubstituted or have one or more substituent selected from the group consisting of halogens, hydroxyl group and alkyl groups; and
R¹⁵ represents an alkyl chain having 8 or more carbon atoms optionally substituted by halogen, and may be linear, branched or alicyclic.

5. The positive resist composition according to claim 4, wherein R¹⁵ represents a fluorocarbon chain obtained by substituting all hydrogen atoms in an alkyl chain having 8 or more carbon atoms by fluorine.

6. The positive resist composition according to claim 1, which comprises the resin in an amount of 80 to 99.9% by weight, and the acid generating agent in an amount of 0.1 to 20% by weight based on total solid content in the composition.

7. The positive resist composition according to claim 6, which further comprises a basic compound as a quencher.

8. The positive resist composition according to claim 7, wherein the amount of the basic compound is 0.001 to 1% by weight based on total solid content in the composition.

9. The positive resist composition according to claim 7, wherein the basic compound is a compound of the following formula: 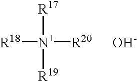
wherein R¹⁷, R¹⁸, R¹⁹ and R²⁰ represent each independently hydrogen, alkyl, cycloalkyl or aryl, wherein the alkyl, cycloalkyl or aryl each independently are unsubstituted or substituted with a hydroxyl group, amino group or alkoxy group having 1 to 6 carbon atoms, and the amino group is unsubstituted or substituted with an alkyl group having 1 to 18 carbon atoms.

10. The positive resist composition according to claim 7, wherein the resin is produced by partial substitution of an acid-unstable group dissociating in the presence of an acid for hydrogen of a hydroxyl group in a resin having a polymerization unit of the general formula (II).

11. The positive resist composition according to claim 1, wherein the resin has two or more polymerization units of the general formula (I) in which R⁸ represents mutually different moieties.
